(19) United States
(12) Patent Application Publication
(10) Pub. No.: US 2025/0201644 A1
(43) Pub. Date: Jun. 19, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Chun-Chu LAI, Taichung City (TW)

(73) Assignee: SILICONWARE PRECISION INDUSTRIES CO., LTD., Taichung City (TW)

(21) Appl. No.: 18/750,600

(22) Filed: Jun. 21, 2024

(30) Foreign Application Priority Data
Dec. 18, 2023 (TW) 112149312

(51) Int. Cl. H01L 23/31; H01L 21/56; H01L 23/00; H01L 23/498

(52) U.S. Cl. CPC H01L 23/3121; H01L 21/56; H01L 23/49811; H01L 23/49838; H01L 24/04; H01L 24/16; H01L 24/32; H01L 24/73; H01L 2224/0401; H01L 2224/16227; H01L 2224/16237; H01L 2224/32225; H01L 2224/73204; H01L 2224/73253; H01L 2924/1815

(57) ABSTRACT

An electronic package and a manufacturing method thereof are provided, in which a plurality of conductive pillars with detachable blocks and a first electronic component with detachable blocks are provided, and the first electronic component, the plurality of detachable blocks and the plurality of conductive pillars are covered with an encapsulating layer, so that the plurality of detachable blocks are exposed from the surface of the encapsulating layer, and then the plurality of detachable blocks are removed to form a plurality of recesses on the surface of the encapsulating layer, so that the plurality of conductive pillars and the first electronic component are exposed from the recesses. Therefore, through the design of the recesses, the contact area between the circuit portion subsequently formed on the encapsulating layer and the encapsulating layer can be increased, thereby preventing from peeling of the circuit portion during thermal cycles.

### BACKGROUND

### 1. Technical Field

The present disclosure relates to a semiconductor packaging technology, and more particularly, to an electronic package that can improve reliability and a manufacturing method thereof.

### 2. Description of Related Art

With the evolution of semiconductor packaging technology, different packaging types have been developed for semiconductor devices. In order to improve electrical functions and save packaging space, different three-dimensional packaging technologies have been developed to integrate integrated circuits with different functions into a single package structure. For example, electronic components with different functions (such as memory, central processing unit, graphics processor, imaging application processor, etc.) can be integrated into the system through stacking design for application in thin and light electronic products.

FIG. 1A to FIG. 1D are schematic cross-sectional views of a manufacturing method of a conventional semiconductor package 1.

As shown in FIG. 1A, a plurality of conductive pillars 13 are formed on a carrier board 6, and a plurality of semiconductor chips 11 are disposed on the carrier board 6, wherein a plurality of conductors 112 are bonded onto and electrically connected to the semiconductor chip 11, the conductors 112 are covered with a protective film 111, and a release layer 60, a metal layer 62 and a passivation layer 61 are sequentially formed on the carrier board 6 for the plurality of conductive pillars 13 to be disposed on the passivation layer 61 by electroplating (the seed layer is not shown).

As shown in FIG. 1B, an encapsulating colloid 15 is formed on the passivation layer 61 of the carrier board 6, such that the encapsulating colloid 15 covers the semiconductor chips 11, the protective film 111 and the conductive pillars 13. Then by removing part of the material of the protective film 111, part of the material of the plurality of conductive pillars 13, part of the material of the plurality of conductors 112, and part of the material of the encapsulating colloid 15 via grinding, the upper surface of the encapsulating colloid 15 is flushed with the protective film 111, the plurality of conductive pillars 13, and the plurality of conductors 112, such that the plurality of conductive pillars 13, the protective film 111, and the plurality of conductors 112 are exposed from the encapsulating colloid 15.

As shown in FIG. 1C, a circuit structure 10 is formed on the encapsulating colloid 15, and the circuit structure 10 is electrically connected to the plurality of conductive pillars 13 and the plurality of conductors 112, wherein the circuit structure 10 includes a plurality of insulation layers 100 and a plurality of circuit layers 101 are provided on the plurality of insulation layers 100.

As shown in FIG. 1D, an electronic component 18 is electrically connected to the circuit layer 101 via a plurality of conductive bumps 180 to be electrically connected to the circuit structure 10, and an underfill 19 is formed between the circuit structure 10 and the electronic component 18 to cover the conductive bumps 180.

In addition, the carrier board 6 and the release layer 60 and the metal layer 62 thereon are removed, and the passivation layer 61 is retained, and then a wiring layer 140 is formed on the passivation layer 61 to be electrically connected to the conductive pillars 13. After that, a plurality of conductive elements 17 such as solder bumps or solder balls can be formed on the wiring layer 140 for connection to other electronic devices, and a singulation process is performed along a cutting path S as shown in FIG. 1C to obtain a semiconductor package. 1.

However, in the manufacturing method of the conventional semiconductor package 1, due to the mismatch in the coefficient of thermal expansion (CTE) between the encapsulating colloid 15 and the semiconductor chip 11, uneven thermal stress is likely to occur. As a result, the encapsulating colloid 15 warps during the thermal cycles of the manufacturing process, causing the circuit structure 10 to occur peeling.

Therefore, how to overcome the above-mentioned problems of the prior art has become a difficult problem that the industry needs to overcome urgently.

### SUMMARY

In view of the various deficiencies of the prior art, the present disclosure provides an electronic package, which comprises: an encapsulating having a first surface and a second surface opposing to each other, wherein a plurality of recesses are formed on the first surface; a first electronic component embedded in the encapsulating layer and exposed from some of the plurality of recesses; and a plurality of conductive pillars embedded in the encapsulating layer and exposed from some of the plurality of recesses.

In the aforementioned electronic package, a detachable block is formed in the recess. For example, the detachable block includes polyimide material or polyoxadiazole benzene material.

The present disclosure also provides a manufacturing method of an electronic package, which comprises: disposing a plurality of conductive pillars and at least one first electronic component on a carrier board, wherein a plurality of detachable blocks are formed on end surfaces of the plurality of conductive pillars and the first electronic component; forming an encapsulating layer on the carrier board, so that the encapsulating layer covers the first electronic component, the plurality of detachable blocks and the plurality of conductive pillars, wherein the encapsulating layer has a first surface and a second surface opposing to each other, such that the plurality of detachable blocks are exposed from the first surface of the encapsulating layer, and the second surface of the encapsulating layer is bonded to the carrier board; and removing the plurality of detachable blocks to form a plurality of recesses on the first surface of the encapsulating layer, so that the plurality of conductive pillars and the first electronic component are exposed from the plurality of recesses.

In the aforementioned method, the detachable block includes polyimide material or polyoxadiazole benzene material.

In the aforementioned electronic package and the manufacturing method thereof, the method further comprises forming a circuit portion on the first surface of the encapsulating layer and in the plurality of recesses, so that the circuit portion is electrically connected to the plurality of conductive pillars and the first electronic component. For example, the circuit portion includes a dielectric layer formed on the first surface and a circuit body embedded in the dielectric layer and extending into the plurality of recesses. Further, the circuit body is electrically connected to the plurality of conductive pillars and the first electronic component. Alternatively, the method may comprise forming a circuit structure on the circuit portion, such that the circuit structure is electrically connected to the circuit portion. Further, the method further comprises disposing a second electronic component on the circuit structure.

In the aforementioned electronic package and the manufacturing method thereof, the carrier board has a passivation layer to be bonded to the second surface of the encapsulating layer, the plurality of conductive pillars and the first electronic component. For example, the method may comprise removing the carrier board. The method further comprises forming a wiring layer on the passivation layer, wherein the wiring layer is electrically connected to the plurality of conductive pillars.

It can be seen from the above that in the electronic package and its manufacturing method of the present disclosure, a recess is formed on the first surface of the encapsulating layer, so that when the circuit portion in the subsequent process is formed on the first surface of the encapsulating layer, the circuit portion will engage the recess, so that the contact area between the encapsulating layer and the circuit portion is increased. Therefore, compared with the prior art, the manufacturing method of the present disclosure can avoid peeling of the circuit portion during thermal cycles, thereby improving the reliability of the electronic package.

### BRIEF DESCRIPTION OF THE DRAWINGS

FIG. 1A to FIG. 1D are schematic cross-sectional views illustrating a manufacturing method of a conventional semiconductor package.

FIG. 2A to FIG. 2F are schematic cross-sectional views illustrating a manufacturing method of an electronic package according to the present disclosure.

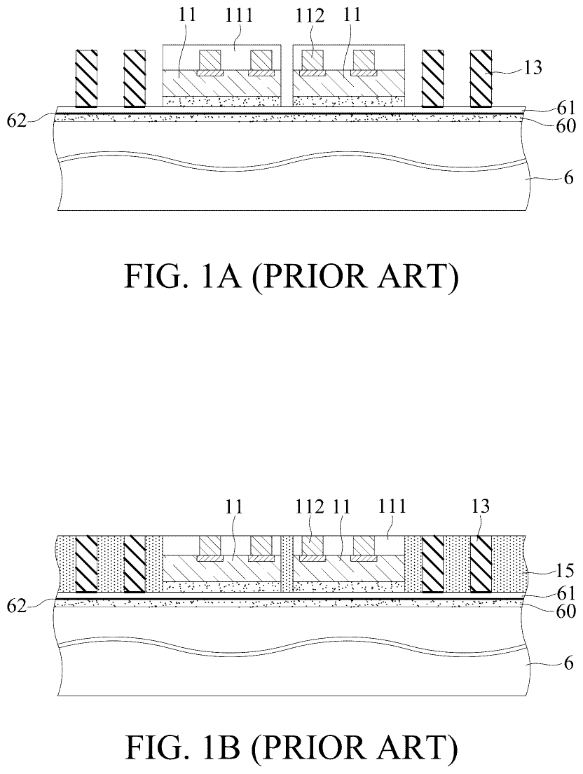

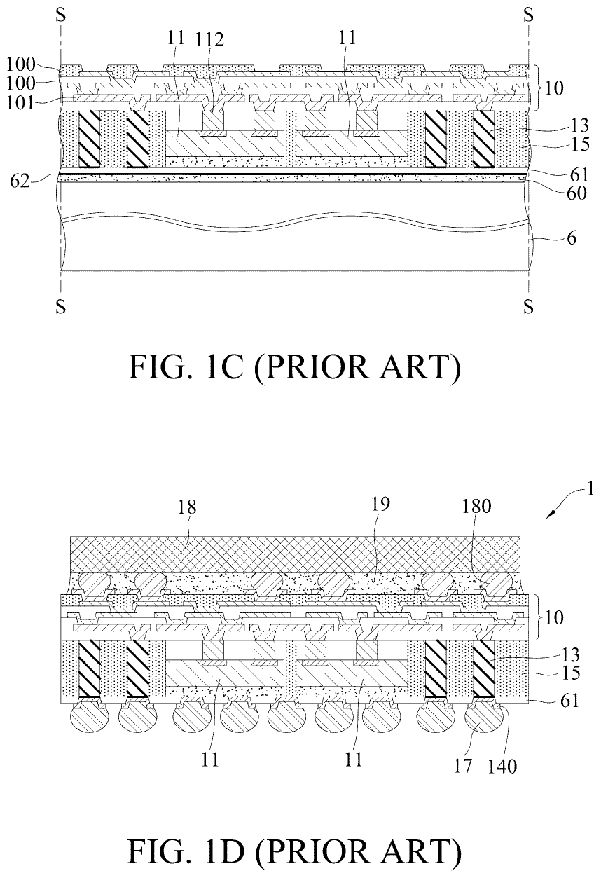

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

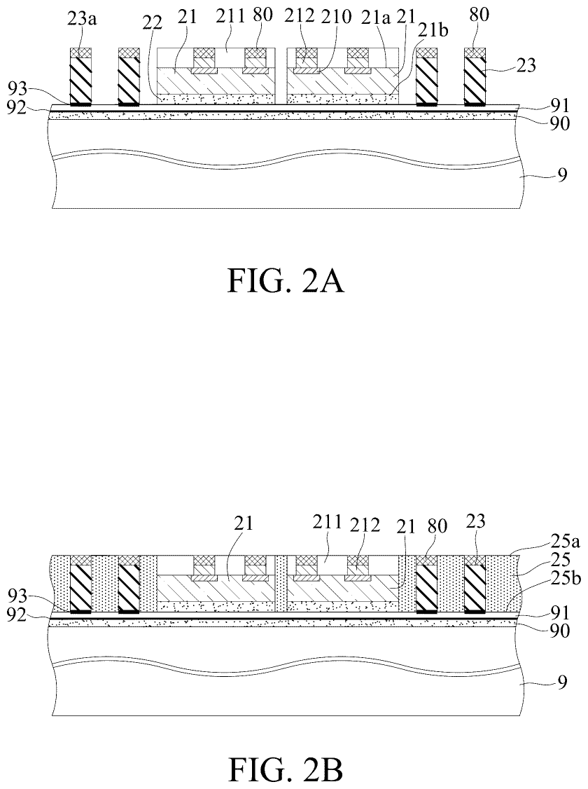

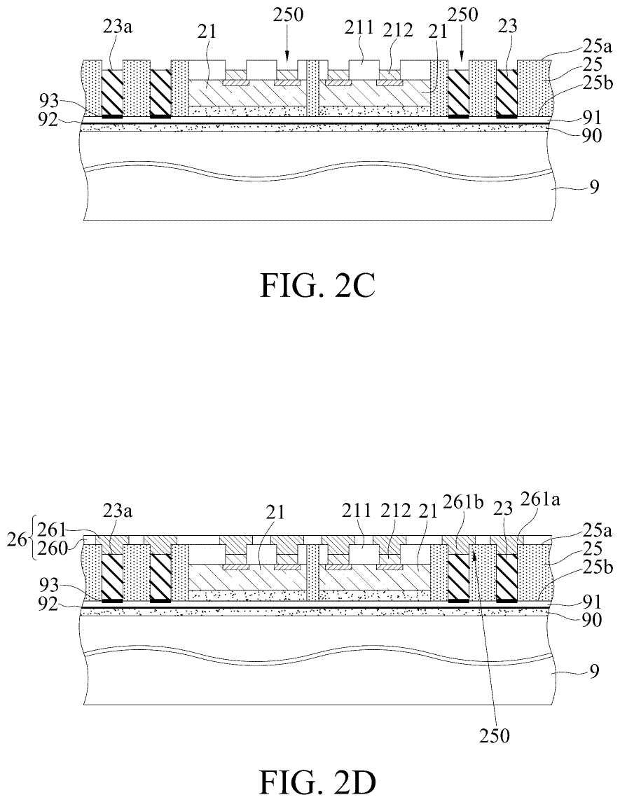

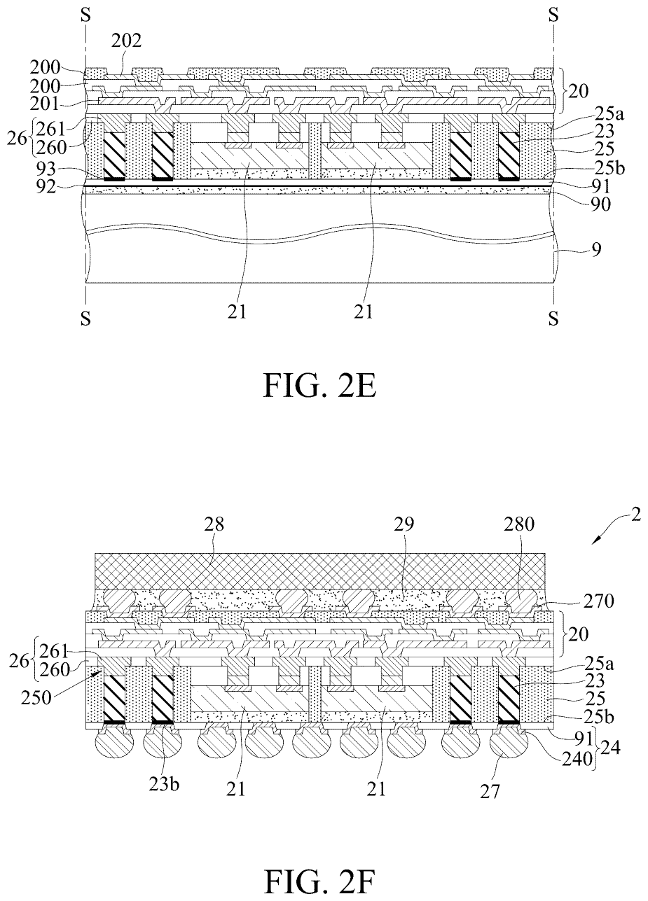

FIG. 2A to FIG. 2F are schematic cross-sectional views of a manufacturing method of an electronic package 2 according to the present disclosure.

As shown in FIG. 2A, a plurality of conductive pillars 23 are formed on a carrier board 9, and at least one first electronic component 21 is disposed on the carrier board 9, wherein a plurality of detachable blocks 80 are formed on end surfaces 23a of the plurality of conductive pillars 23 and the first electronic component 21.

The carrier board 9 is, for example, a board made of semiconductor material (such as silicon or glass), on which a release layer 90, a metal layer 92 such as titanium/copper, and a passivation layer 91 such as a dielectric material or solder mask are sequentially formed by, for example, coating, and a conductive seed layer 93 such as titanium/copper is formed on the passivation layer 91 for the conductive pillars 23 to be disposed on the passivation layer 91 via a patterning process.

The detachable block 80 may be composed of water-soluble materials, which may include polyimide (PI) material or polybenzoxazole (PBO) material.

The conductive pillar 23 is made of metal such as copper or solder material, but is not limited to this.

The first electronic component 21 is an active element, a passive element or a combination of both, wherein the active element is, for example, a semiconductor chip, and the passive element is, for example, a resistor, a capacitor, and an inductor.

In an embodiment, the first electronic component 21 is a semiconductor chip, which has an active surface 21a and an non-active surface 21b opposing to each other, wherein the non-active surface 21b of the first electronic component 21 is adhered to the passivation layer 91 via a bonding layer 22, the active surface 21a has a plurality of electrode pads 210 and a protective film 211 made of passivation material, and conductors 212 are bonded to and electrically connected to the electrode pads 210 and are disposed in the protective film 211. For example, the conductor 212 is a spherical shape such as a conductive circuit, a solder ball, a columnar shape of metal such as a copper pillar, a solder bump, or a stud-shaped conductive member made by a wire bonding machine.

Furthermore, the first electronic component 21 is bonded to the detachable block 80 on the top of the conductor 212 thereon.

As shown in FIG. 2B, an encapsulating layer 25 is formed on the passivation layer 91 of the carrier board 9, such that the encapsulating layer 25 covers the first electronic components 21, the protective film 211 and the conductive pillars 23, wherein the encapsulating layer 25 has a first surface 25a and a second surface 25b opposing to each other, so that the second surface 25b of the encapsulating layer 25 is bonded to the passivation layer 91 of the carrier board 9, and the protective film 211 and the plurality of detachable blocks 80 are exposed from the first surface 25a of the encapsulating layer 25.

In an embodiment, the encapsulating layer 25 is an insulating material, such as polyimide (PI), dry film, encapsulating colloid such as epoxy resin (epoxy) or encapsulating material (molding compound). For example, the encapsulating layer 25 may be formed on the passivation layer 91 by liquid compound, injection, lamination or compression molding.

Furthermore, a leveling process can be used to make the first surface 25a of the encapsulating layer 25 flush with the protective film 211 and the separable block 80, such that the detachable block 80 is exposed from the first surface 25a of the encapsulating layer 25. For example, the leveling process removes part of the material of the protective film 211, part of the material of the detachable block 80, and part of the material of the encapsulating layer 25 via grinding.

As shown in FIG. 2C, the detachable blocks 80 are removed by etching, etc., to form a plurality of recesses 250 on the first surface 25a of the encapsulating layer 25, so that the end surfaces 23a of the conductive pillars 23 and the conductors 212 are respectively exposed from the recesses 250.

As shown in FIG. 2D, a circuit portion 26 is formed on the first surface 25a of the encapsulating layer 25 and in the recesses 250, so that the circuit portion 26 is electrically connected to the conductive pillars 23 and the plurality of conductors 212 on the first electronic component 21.

In an embodiment, the circuit portion 26 includes a dielectric layer 260 formed on the first surface 25a and a circuit body 261 disposed on the dielectric layer 260 (for example, embedded in the dielectric layer 260) and extending into the recesses 250. For example, the circuit body 261 has a plurality of conductive traces 261a combined with the first surface 25a and a plurality of conductive blind holes 261b electrically connected to the conductive traces 261a and located in the recess 250, such that upper surfaces of the conductive traces 261a are flush with the upper surface of the dielectric layer 260, such that the conductive traces 261a are exposed from the upper surface of the dielectric layer 260.

As shown in FIG. 2E, a circuit structure 20 is formed on the circuit portion 26, and the circuit structure 20 is electrically connected to the circuit body 261.

In an embodiment, the circuit structure 20 includes a plurality of insulation layers 200 and a plurality of circuit layers 201 disposed on the insulation layer 200, such as redistribution layer (RDL) specifications, and the outermost insulation layer 200 can be used as a solder mask, such that the outermost circuit layer 201 is exposed from the solder mask to serve as an electrical contact pad 202. Alternatively, the circuit structure 20 may only include a single insulation layer 200 and a single circuit layer 201.

Furthermore, the material for forming the circuit layer 201 is copper, and the material for forming the insulation layer 200 is a dielectric material such as polybenzoxazole (PBO), polyimide (PI), prepreg (PP) and the like, or a solder resist material such as solder mask, ink, etc.

As shown in FIG. 2F, at least one second electronic component 28 is disposed on the circuit structure 20, wherein the carrier board 9 and the release layer 90 and the metal layer 92 thereon are removed to form a wiring structure 24 on the second surface 25a of the encapsulating layer 25 for bonding the conductive elements 27, and a singulation process is performed along a cutting path S as shown in FIG. 2E to manufacture an electronic package 2 of the present disclosure.

The second electronic component 28 is, for example, an active element, a passive element, a package structure or a combination thereof, wherein the active element is, for example, a semiconductor chip, and the passive element is, for example, a resistor, a capacitor, and an inductor.

In an embodiment, the second electronic component 28 is a semiconductor chip, which can be disposed on the electrical contact pads 202 of the circuit structure 20 in a flip-chip manner via a plurality of conductive bumps 280 such as solder bumps, copper bumps or others and electrically connected to the circuit layer 201, and the conductive bumps 280 are covered with an underfill 29; alternatively, the second electronic component 28 can be electrically connected to the circuit layer 201 in a wire bonding manner via a plurality of bonding wires; alternatively, the second electronic component 28 may directly contact the circuit layer 201. It should be understood that there are many ways for the second electronic component 28 to be electrically connected to the circuit structure 20 and are not limited to the above.

In addition, an under bump metallurgy (UBM) 270 can be formed on the electrical contact pad 202 to facilitate bonding with the conductive bump 280.

In addition, after removing the carrier board 9 and the release layer 90 and the metal layer 92 thereon, the passivation layer 91 is retained, and a wiring layer 240 is formed on the passivation layer 91, wherein the wiring layer 240 and the passivation layer 91 are served as a wiring structure 24, such that the wiring layer 240 is electrically connected to the conductive pillar 23.

In an embodiment, the passivation layer 91 is formed with a plurality of openings by laser, such that end surfaces 23b of the conductive pillars 23 and part of the second surface 25b of the encapsulating layer 25 are exposed from the openings for bonding to the wiring layer 240. For example, the wiring layer 240 is an under-bump metal layer (UBM) to be bonded to a plurality of conductive elements 27 such as solder bumps or solder balls for external connection to an electronic device such as a circuit board (not shown); alternatively, a wiring layer (not shown) can be formed on the passivation layer 91 via an RDL process to be bonded to the conductive elements 27 or UBM. It should be understood that there are many types of wiring layer 240 and there is no particular limitation.

Therefore, the manufacturing method of the present disclosure mainly forms the recess 250 on the first surface 25a of the encapsulating layer 25 via the design of the detachable block 80, so that the contact area between the encapsulating layer 25 and the circuit portion 26 increases, for example, the circuit body 261 is embedded in the recessed portion 250. Therefore, compared with the prior art, the manufacturing method of the present disclosure will not occur peeling of the circuit portion 26 even if the encapsulating layer 25 warps during thermal cycles. Therefore, the reliability of the electronic package 2 is effectively improved.

The present disclosure also provides an electronic package 2, which comprises: an encapsulating layer 25, at least one first electronic component 21 and a plurality of conductive pillars 23.

The encapsulating layer 25 has a first surface 25a and a second surface 25b opposing to each other, wherein a plurality of recesses 250 are formed on the first surface 25a.

The first electronic component 21 is embedded in the encapsulating layer 25 and exposed from some of the plurality of recesses 250.

The plurality of conductive pillars 23 are embedded in the encapsulating layer 25 and exposed from some of the plurality of recesses 250.

In an embodiment, a detachable block 80 is formed in the recess 250. For example, the detachable block 80 may include polyimide material or polyoxadiazole benzene material.

In an embodiment, the electronic package 2 further includes a circuit portion 26 formed on the first surface 25a and in the plurality of recesses 250, and the circuit portion 26 is electrically connected to the plurality of conductive pillars 23 and the first electronic component 21. For example, the circuit portion 26 includes a dielectric layer 260 formed on the first surface 25a and a circuit body 261 is embedded in the dielectric layer 260 and extending to the plurality of recesses 250. Furthermore, the circuit body 261 is electrically connected to the conductive pillar 23 and the first electronic component 21. Alternatively, the electronic package 2 further includes a circuit structure 20 formed on the circuit portion 26, such that the circuit structure 20 is electrically connected to the circuit portion 26, and may further include a second electronic component 28 disposed on the circuit structure 20.

In one embodiment, a passivation layer 91 is bonded onto the second surface 25b of the encapsulating layer 25. For example, the electronic package 2 further includes a wiring layer 240 formed on the passivation layer 91, and the wiring layer 240 is electrically connected to the plurality of conductive pillars 23.

To sum up, in the electronic package and its manufacturing method of the present disclosure, the design of the detachable block is used to form a recess on the first surface of the encapsulating layer, so that the circuit portion is disposed on the first surface of the encapsulating layer and extends into the recess, such that the contact area between the encapsulating layer and the circuit portion is increased. Therefore, compared with the prior art, the manufacturing method of the present disclosure will not occur peeling of the circuit portion even if the encapsulating layer warps during thermal cycles. Therefore, the reliability of the electronic package is effectively improved.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
an encapsulating layer having a first surface and a second surface opposing to each other, wherein a plurality of recesses are formed on the first surface;
a first electronic component embedded in the encapsulating layer and exposed from some of the plurality of recesses; and
a plurality of conductive pillars embedded in the encapsulating layer and exposed from some of the plurality of recesses.

2. The electronic package of claim 1, wherein a detachable block is formed in the recess.

3. The electronic package of claim 2, wherein the detachable block includes polyimide material or polyoxadiazole benzene material.

4. The electronic package of claim 1, further comprising a circuit portion formed on the first surface and in the plurality of recesses, wherein the circuit portion is electrically connected to the plurality of conductive pillars and the first electronic component.

5. The electronic package of claim 4, wherein the circuit portion includes a dielectric layer formed on the first surface and a circuit body embedded in the dielectric layer and extending into the plurality of recesses.

6. The electronic package of claim 5, wherein the circuit body is electrically connected to the plurality of conductive pillars and the first electronic component.

7. The electronic package of claim 4, further comprising a circuit structure formed on the circuit portion, such that the circuit structure is electrically connected to the circuit portion.

8. The electronic package of claim 7, further comprising a second electronic component disposed on the circuit structure.

9. The electronic package of claim 1, wherein a passivation layer is bonded to the second surface of the encapsulating layer.

10. The electronic package of claim 9, further comprising a wiring layer formed on the passivation layer, wherein the wiring layer is electrically connected to the plurality of conductive pillars.

11. A manufacturing method of an electronic package, comprising:
disposing a plurality of conductive pillars and a first electronic component on a carrier board, wherein a plurality of detachable blocks are formed on end surfaces of the plurality of conductive pillars and the first electronic component;
forming an encapsulating layer on the carrier board, so that the encapsulating layer covers the first electronic component, the plurality of detachable blocks and the plurality of conductive pillars, wherein the encapsulating layer has a first surface and a second surface opposing to each other, such that the second surface of the encapsulating layer is bonded to the carrier board, and that the plurality of detachable blocks are exposed from the first surface of the encapsulating layer; and
removing the plurality of detachable blocks to form a plurality of recesses on the first surface of the encapsulating layer, so that the plurality of conductive pillars and the first electronic component are exposed from the plurality of recesses.

12. The manufacturing method of claim 11, wherein the detachable block includes polyimide material or polyoxadiazole benzene material.

13. The manufacturing method of claim 11, further comprising forming a circuit portion on the first surface of the encapsulating layer and in the plurality of recesses, so that the circuit portion is electrically connected to the plurality of conductive pillars and the first electronic component.

14. The manufacturing method of claim 13, wherein the circuit portion includes a dielectric layer formed on the first surface and a circuit body embedded in the dielectric layer and extending into the plurality of recesses.

15. The manufacturing method of claim 14, wherein the circuit body is electrically connected to the plurality of conductive pillars and the first electronic component.

16. The manufacturing method of claim 13, further comprising forming a circuit structure on the circuit portion, such that the circuit structure is electrically connected to the circuit portion.

17. The manufacturing method of claim 16, further comprising disposing a second electronic component on the circuit structure.

18. The manufacturing method of claim 11, wherein the carrier board has a passivation layer to be bonded to the second surface of the encapsulating layer, the plurality of conductive pillars and the first electronic component.

19. The manufacturing method of claim 18, further comprising removing the carrier board.

20. The manufacturing method of claim 19, further comprising forming a wiring layer on the passivation layer, wherein the wiring layer is electrically connected to the plurality of conductive pillars.
